(19) United States
(12) Patent Application Publication
(10) Pub. No.: US 2026/0052910 A1
(43) Pub. Date: Feb. 19, 2026

(54) MAGNETIC MEMORY DEVICE AND METHOD FOR FORMING THE SAME

(71) Applicant: UNITED MICROELECTRONICS CORP., Hsin-Chu City (TW)

(72) Inventors: Chih-Wei Kuo, Tainan City (TW); Chung-Yi Chiu, Tainan City (TW)

(73) Assignee: UNITED MICROELECTRONICS CORP., Hsin-Chu City (TW)

(21) Appl. No.: 18/898,710

(22) Filed: Sep. 27, 2024

(30) Foreign Application Priority Data
Aug. 13, 2024 (TW) 113130308

(51) Int. Cl. H10N 50/80; H10B 61/00; H10N 50/01; H10N 50/10

(52) U.S. Cl. CPC H10N 50/80; H10B 61/00; H10N 50/01; H10N 50/10

(57) ABSTRACT

A MRAM device includes a memory stack structure having a bottom electrode, a magnetic tunneling junction (MTJ) on the bottom electrode, and a top electrode on the MTJ, wherein an upper portion of the top electrode comprises an arc-shaped recess. An interconnecting structure is disposed on the top electrode and filling the arc-shaped recess.

### BACKGROUND OF THE INVENTION

### 1. Field of the Invention

The present invention relates to the field of semiconductor manufacturing technology, particularly to a magnetic memory device and method for forming a magnetic memory device.

### 2. Description of the Prior Art

Magnetoresistive random access memory (MRAM) is a new type of memory that has gained significant attention in recent years on the merit of integrating the advantages of various existing memory types, such as access speeds comparable to static random access memory (SRAM), non-volatility and low power consumption comparable to flash memory, high density and durability comparable to dynamic random access memory (DRAM). Furthermore, the manufacturing process for MRAM may be conveniently incorporated into existing back end semiconductor manufacturing processes. Therefore, MRAM has the potential to become the primary memory used in semiconductor chips.

Magnetoresistive random access memory (MRAM) includes memory cell structures disposed between the upper-layer interconnection structures and the lower-layer interconnection structures. The memory cell structures respectively include a magnetic tunneling junction (MTJ). Unlike traditional memory that stores data by electric charges, the MRAM cell stores data by applying an external magnetic field to control the magnetic polarity and tunneling magnetoresistance (TMR) of the MTJ of the cell. For example, a high TMR state represents data “1”, while a low TMR state represents data “0”. The ratio of the difference between the resistances of the high TMR state and the low TMR state to the resistance of the low TMR state is referred to as the TMR ratio. A higher TMR ratio may provide a larger read margin, improving the data read speed and reliability of the device.

### SUMMARY OF THE INVENTION

The present invention is direct to provide a magnetic memory device and a method for forming a magnetic memory device. The magnetic memory device provided by the present invention may ensure sufficient contact area and stable contact resistance between the top electrode of the memory cell structure and the interconnection structure, thereby achieving more stable tunneling magnetoresistance and a higher TMR ratio. The better performance of the magnetic memory device may be obtained.

An embodiment of the present invention discloses a method for forming a magnetic memory device, which includes forming a memory cell structure on a substrate. The memory cell structure includes a bottom electrode, a magnetic tunnel junction (MTJ) on the bottom electrode, and a top electrode on the magnetic tunnel junction. Next, a dielectric layer is formed to cover the substrate and the memory cell structure, and then a trench is formed in the dielectric layer to expose an upper portion of the top electrode. Subsequently, an etching process is performed on the top electrode to form an arc-shaped recess in the upper portion of the top electrode, wherein the arc-shaped recess is below a bottom surface of the trench. Subsequently, a conductive material is formed to fill the trench and the arc-shaped recess.

Another embodiment of the present invention discloses a magnetic memory device, which includes a memory cell structure disposed on a substrate. The memory cell structure includes a bottom electrode, a magnetic tunnel junction (MTJ) on the bottom electrode, and a top electrode on the magnetic tunnel junction. An upper portion of the top electrode includes an arc-shaped recess. An interconnection structure is disposed on the top electrode and fills the arc-shaped recess.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 are schematic cross-sectional diagrams illustrating the steps for forming a magnetic memory device according to an embodiment of the present invention.

### DETAILED DESCRIPTION

To provide a better understanding of the present invention to those of ordinary skill in the art, several exemplary embodiments of the present invention will be detailed as follows, with reference to the accompanying drawings using numbered elements to elaborate the contents and effects to be achieved.

The drawings of the present invention are schematic and not drawn to scale. Some components may be enlarged for clarity. The same reference signs are generally used to refer to corresponding or similar features in modified and different embodiments. The spatial terms mentioned in the specification, such as “below”, “low”, “down”, “above”, “on top”, “over”, “top”, “bottom”, or the like, are understood by those skilled in the art to describe the relative spatial relationship of one component or feature to another (or multiple) components or features in the drawings. Any rotation (such as rotating 90 degrees or in other orientations) will still conform to the spatial descriptions in the specification.

In this specification, a “substrate” refers to any structure that has an exposed surface on which materials may be deposited according to the embodiments of the present invention to manufacture integrated circuit structures. A “substrate” also refers to a semiconductor structure that includes material layers formed on it during the manufacturing process. When a component or layer is referred to as “on another component or layer” or “connected to another component or layer,” it may be directly on or directly connected to another component or layer, or may be indirectly on or indirectly connected to another component or layer with other components or layers present therebetween. On the contrary, when a component is referred to as “directly on another component or layer” or “directly connected to another component or layer,” there are no intervening components or layers disposed therebetween. The terms “equal”, “equivalent”, “identical”, or “substantially” are generally interpreted as being within 20% of a given value or range, or interpreted as being within 10%, 5%, 3%, 2%, 1%, or 0.5% of a given value or range. There may be a certain amount of error between any two values or directions used for comparison.

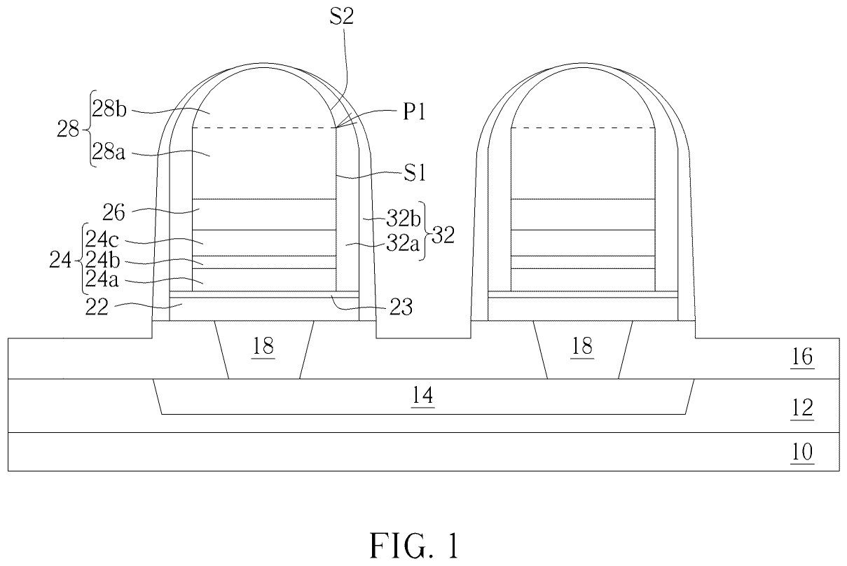

Please refer to FIG. 1 to FIG. 5, which are schematic cross-sectional diagrams illustrating the steps for forming a magnetic memory device according to an embodiment of the present invention. First, as shown in FIG. 1, a substrate 10 is provided, and at least a dielectric layer and an interconnection structure in the dielectric layer are formed on the substrate 10. Subsequently, memory cell structures MC are formed on the substrate 10. Spacer structures 32 are then formed on sidewalls of the memory cell structures MC.

The substrate 10, for example, may be a silicon substrate, a silicon-on-insulator (SOI) substrate, a III-V semiconductor substrate, but is not limited thereto. The substrate 10 may include manufactured semiconductor components, such as transistors, capacitors, resistors, inductors, etc., which are not shown in the diagrams for the sake of simplification.

At least a dielectric layer and interconnect structures formed in the dielectric layer may be formed on the substrate 10. For example, as shown in FIG. 1, a dielectric layer 12 and a dielectric layer 16 may be sequentially formed on the substrate 10. At least an interconnection structure 14 may be (such as metal interconnect structures) formed in the dielectric layer 12. A plurality of interconnect structures interconnect structures (such as contact vias) 18 may be formed in the dielectric layer 16 and in direct contact with the interconnect structures 14. The dielectric layer 12 and the dielectric layer 16 respectively include silicon oxide (SiO₂) or a suitable low-k dielectric material such as fluorinated silica glass (FSG), silicon oxycarbide (SiCOH), spin-on-glass, porous low-k dielectric material, organic dielectric polymers, or a combination thereof, but is not limited thereto. The interconnect structures 14 and the interconnect structures 18 respectively include a conductive metal or a metal compound, such as tungsten (W), copper (Cu), aluminum (Al), titanium (Ti), tantalum (Ta), titanium nitride (TiN), tantalum nitride (TaN), or a combination thereof, but is not limited thereto.

The memory cell structure MC is disposed on the dielectric layer 16. The composition and films of the s memory cell structure MC may be adjusted according to the type of magnetic memory device. In this embodiment, the magnetic memory device may be spin-orbit torque (SOT) magnetic memory device, and each of the memory cell structure MC includes, from bottom to top, a bottom electrode 22 that is in direct contact with an interconnect structure 18, a spin-orbit torque (SOT) layer 23 disposed on the bottom electrode 22, a magnetic tunneling junction (MTJ) 24 disposed on the SOT layer 23, a cap layer 26 disposed on the magnetic tunneling junction 24, and a top electrode 28 disposed on the cap layer 26. The bottom electrode 22 and the top electrode 28 respectively include a conductive metal or a metal compound, such as titanium (Ti), tantalum (Ta), titanium nitride (TiN), tantalum nitride (TaN), platinum (Pt), copper (Cu), gold (Au), aluminum (Al), or a combinations thereof, but is not limited thereto. The SOT layer 23 may include a heavy metal material with strong spin-orbit coupling, such as tantalum (Ta), tungsten (W), platinum (Pt), but is not limited thereto. The magnetic tunneling junction 24 has a multilayer structure, including a free layer 24a, a fixed layer 24c, and a tunneling barrier layer 24b disposed between the free layer 24a and the fixed layer 24c. The free layer 24a and the fixed layer 24c respectively include a ferromagnetic material, such as iron (Fe), cobalt (Co), nickel (Ni), iron-nickel (FeNi), iron-cobalt (FeCo), cobalt-nickel (CoNi), iron-boron (FeB), iron-platinum (FePt), iron-palladium (FePd), cobalt-iron-boron (CoFeB), and other suitable ferromagnetic materials or a combination thereof, but is not limited thereto. The magnetic polarity of the fixed layer 24c is pinned in a single direction by an adjacent antiferromagnetic reference layer (not shown). The magnetic polarity of the free layer 24a may be flipped to be parallel or antiparallel to the magnetic polarity of the fixed layer 24c by an external magnetic field. The tunneling barrier layer 24b contains insulating materials, such as a metal oxides selected from magnesium oxide (MgO), aluminum oxide (AlO), nickel oxide (NiO), gadolinium oxide (GdO), tantalum oxide (TaO), molybdenum oxide (MoO), titanium oxide (TiO), tungsten oxide (WO), or a combinations thereof, but is not limited thereto. The cap layer 26 may include a metal material or a metal oxide, such as aluminum (Al), magnesium (Mg), tantalum (Ta), ruthenium (Ru), magnesium oxide (MgO), aluminum oxide (AlO), nickel oxide (NiO), gadolinium oxide (GdO), tantalum oxide (TaO), molybdenum oxide (MoO), titanium oxide (TiO), tungsten oxide (WO), or a combination thereof, but is not limited thereto. The compositions and stacking order of the component layers of the memory cell structure MC illustrated in the embodiment are examples and may be modified in other embodiments for design needs. Each component layer of the memory cell structure MC may be single-layered multiple-layered with a thickness ranging from approximately a few angstroms (Å) to several tens of nanometers (nm).

The spacer structure 32 is disposed on the sidewall of the memory cell structure MC and may be single-layered or multi-layered. In this embodiment, the spacer structure 32 includes a first spacer layer 32a and a second spacer layer 32b, wherein the first spacer layer 32a is disposed on the top surface of the bottom electrode 22 and covers the sidewalls of the SOT layer 23, the magnetic tunnel junction stack 24, the cap layer 26, and the top electrode 28. The second spacer layer 32b is disposed on the dielectric layer 16 and covers the sidewall of the bottom electrode 22 and the first spacer layer 32a. The spacer layer 32a and the second spacer layer 32b respectively include a dielectric material such as silicon nitride (SiN), silicon oxynitride (SiON), silicon carbonitride (SiCN), or a combinations thereof, but is not limited thereto.

The steps for forming the memory cell structures MC may include the steps of continuously performing film deposition processes to form a stacked material layer of the memory cell structure MC on the dielectric layer 16, wherein the stacked material layer includes, from bottom to top, a bottom electrode material layer, a SOT material layer, a magnetic tunnel junction material layer, a cap material layer, and a top electrode material layer. Subsequently, an annealing process may be performed to promote film crystallization of the magnetic tunnel junction, improving the junction quality and determining the magnetic polarity. The temperature of the annealing process may range from approximately 350° C. to 450° C., and the annealing time may range from about 30 minutes to 5 hours, but is not limited thereto. After the annealing process, an etching process is carried out to remove the excess portions of the stacked material layer and pattern the stacked material layer into a plurality of memory cell structures MC.

In some embodiments, the etching process to pattern the stacked material layer includes multiple etching steps, wherein the first spacer layer 32a and the second spacer layer 32b of the spacer structure 32 are integrally formed by the etching stages. In some embodiments, the method for patterning stacked material layer includes forming a patterned photoresist layer on the stacked material layer and then using the patterned photoresist layer as an etching mask to perform a first etching step to remove parts of the top electrode material layer until the surface of the cap material layer is exposed, thereby obtaining the top electrode 28. Next, the top electrode 28 is used as an etching mask to perform a second etching step to remove parts of the cap material layer and the magnetic tunneling junction material layer until the surface of the SOT material layer is exposed, thereby obtaining the cap layer 26 and the magnetic tunneling junction 24. Subsequently, a first spacer material layer is formed to conformally cover the top surface and sidewalls of the top electrode 28, the sidewalls of the cap layer 26 and the magnetic tunneling junction 24, and the surface of the SOT material layer. Following, a third etching step is performed to remove the portion of the first spacer material layer on the surface of the SOT material layer, thereby obtaining the first spacer layer 32a covering the top surface and sidewalls of the top electrode 28and the sidewalls of the cap layer 26 and the magnetic tunneling junction 24. The first spacer layer 32a is used as an etching mask to etch the SOT material layer and the bottom electrode material layer until the surface of the dielectric layer 16 is exposed, thereby obtaining the SOT layer 23 and the bottom electrode 22 and the memory cell structure MC. In some embodiments, when the first spacer material layer on the top surface of the top electrode 28 is completely removed during the third etching step, the exposed top electrode 28 may also serve as an etching mask when etching the SOT material layer and the bottom electrode material layer. After obtaining the memory cell structure MC and the first spacer layer 32a, a second spacer material layer is then formed to conformally cover the top surface and sidewalls of the memory cell structure MC and the surface of the dielectric layer 16. A fourth etching step is then performed to remove the portion of the second spacer material layer on the surface of the dielectric layer 16, thereby obtaining the second spacer layer 32b that covers the sidewalls of the first spacer layer 32a, the SOT layer 23, and the bottom electrode 22. The first etching step, second etching step, third etching step, and fourth etching step may include reactive ion etching (RIE), ion beam etching (IBE), or a combination thereof, but is not limited thereto. In some embodiments, before forming the first spacer material layer, an oxidation process or a trimming etching process may be performed to oxidize or etch away metal etching byproducts that are redeposited on the sidewalls of the magnetic tunneling junction 24 during the second etching step, preventing TMR failure due to sidewall conductivity of the tunneling barrier layer 24b caused by the metal etching byproducts. The first spacer layer 32a may protect the sidewalls of the magnetic tunneling junction 24 from damage and contamination when etching the SOT material layer and the bottom electrode material layer. The above method of forming the memory cell structure MC and the spacer structure 32 by multi-step etching is merely an example and should not be taken as a limitation of the present invention. In practice, the etching process for forming the memory cell structure MC may include additional etching steps, omit or combine some etching steps based on the design of the memory cell structure MC and the spacer structure 32.

It is worth noting that when the top electrode 28 is used as an etching mask during the etching process, it would also be subjected to ion bombardment and be shaped into a bullet-like profile. As shown in FIG. 1, the top electrode 28 may include a lower portion 28a with a straight sidewall S1 and an upper portion 28b with a conical sidewall S2. The conical sidewall S2 has a curved profile, having tangent lines of gradient angle with the surface of the substrate 10. The upper end of the straight sidewall S1 and the lower end of the conical sidewall S2 are connected at the point P1. The ratio of the thickness of the lower portion 28a and the thickness of the upper portion 28b may be modified by adjusting the process parameters of the etching process, such as adjusting the angle of the ion bombardment. In some embodiments, the lower portion 28a and the upper portion 28b are respectively approximately half of the overall height (or overall thickness) of the top electrode 28. In other words, the thickness of the lower portion 28a and a thickness of the upper portion 28b have a ratio of approximately 1:1. In other embodiments, the lower portion 28a may be more than half of the height of the top electrode 28.

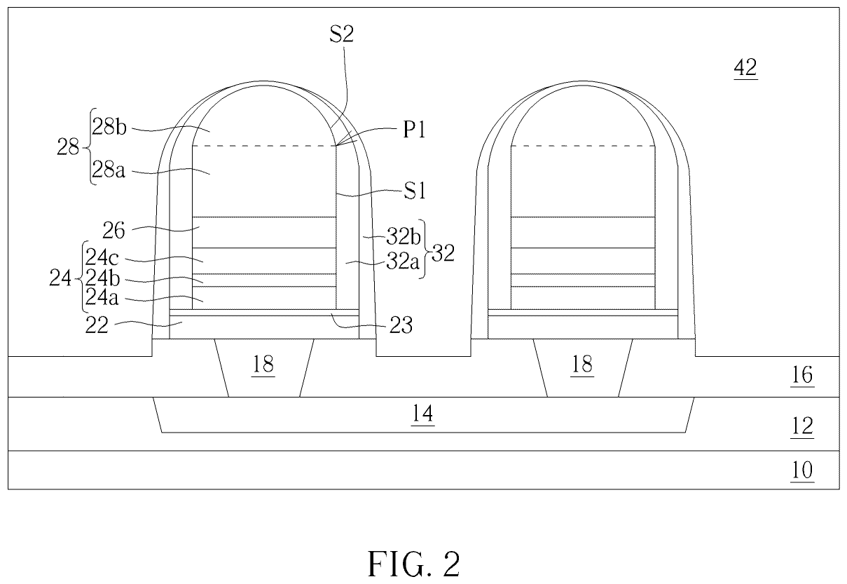

Please refer to FIG. 2. Next, a dielectric layer 42 is formed and completely covers the substrate 10 and the memory cell structure MC. A chemical mechanical polishing (CMP) process is performed to planarize the surface of the dielectric layer 42 and remove part of the dielectric layer 42 until a predetermined thickness. After the CMP process, the top of the memory cell structure MC is still covered by the dielectric layer 42 and is not exposed. The material of the dielectric layer 42 may include a low dielectric constant (low-k) material such as fluorinated silica glass (FSG), silicon carbon oxide (SiCOH), spin-on glass, porous low-k dielectric materials, organic polymer dielectric materials, or a combination thereof, but is not limited thereto.

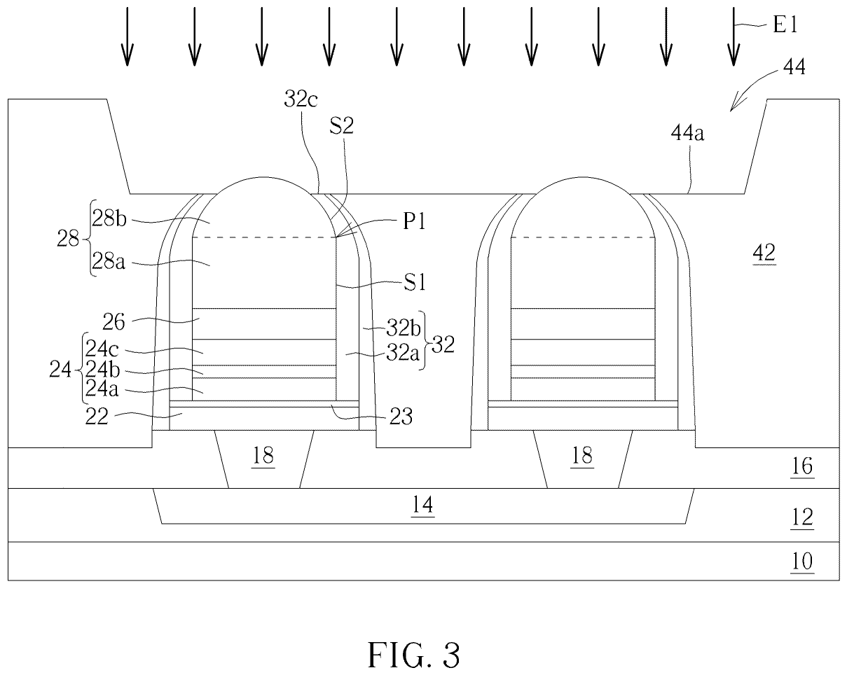

Please refer to FIG. 3. Next, an etching process E1 is performed to remove part of the dielectric layer 42, thereby forming a trench 44 directly above the memory cell structure MC. The depth of the bottom surface 44a of the trench 44 is preferably controlled to be slightly lower than the top surface of the memory cell structure MC to expose the portion of the spacer structure 32 on top of the memory cell structure MC and prevent damage or over etching of the top electrode 28. The expose portion of the spacer structure 32 is then removed by a wet etching, thereby exposing part of the upper portion 28a of the top electrode from the bottom surface 44a of the trench 44.

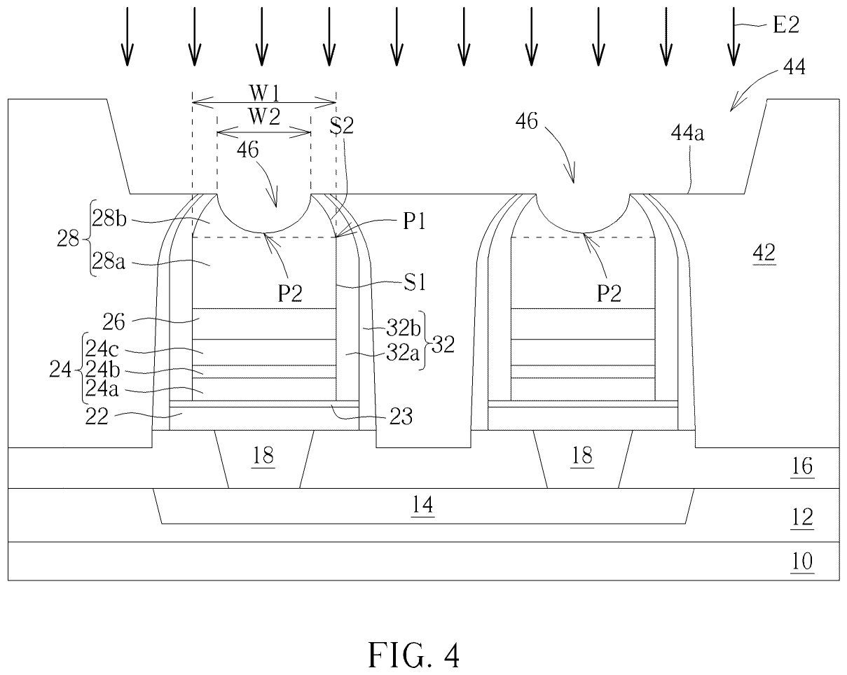

Please refer to FIG. 4. Subsequently, an etching process E2 such as a selectively wet etching process is carried out to selectively and isotropically etching the top electrode 28 to form an arc-shaped recess 46 in the upper portion 28b of the top electrode 28. The etching process E2 may use amine-based solvents, but is not limited thereto. The size of the arc-shaped recess 4 is controlled by the etching process E2. The edge of the arc-shaped recess 46 borders the first spacer layer 32a of the spacer structure 32. According to a preferred embodiment of the present invention, the width W2 of the opening of the arc-shaped recess 46 is less than the width W1 of the lower portion 28a of the top electrode 28, and the depth of the arc-shaped recess 46 does not exceed the thickness of the upper portion 28b, meaning that the lowest point P2 of the arc-shaped recess 46 is not lower than the lower end (that is, the point P1) of the conical sidewall S2 of the upper portion 28b.

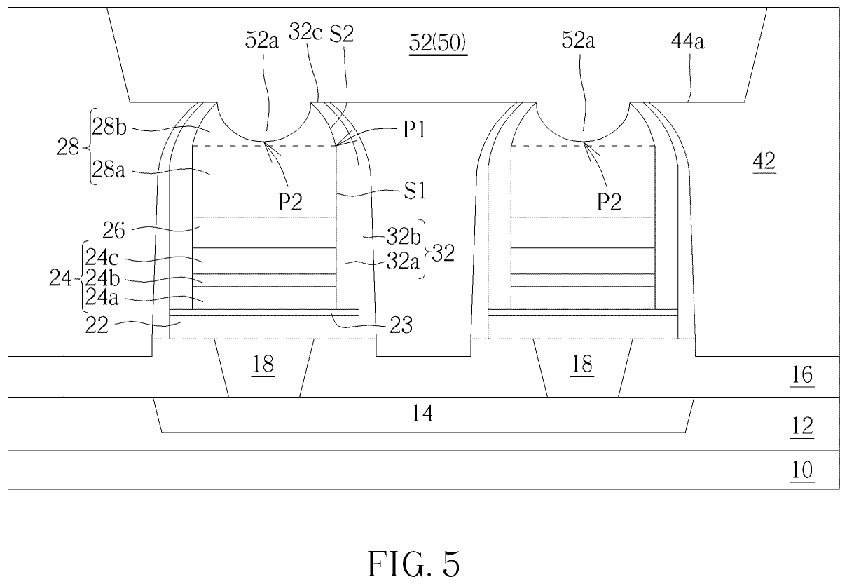

Please refer to FIG. 5. Next, a conductive material 50 is formed on the dielectric layer 42 and filling the trench 44 and the arc-shaped recess 46. A chemical mechanical polishing (CMP) is performed to remove the portion of conductive material 50 on the dielectric layer 42, thereby obtaining a monolithic interconnection structure 52 in the trench 46. The conductive material 50 may include a metal material or a metal compound, such as tungsten (W), copper (Cu), aluminum (Al), titanium (Ti), tantalum (Ta), titanium nitride (TiN), tantalum nitride (TaN), or a combination thereof, but is not thereto. The bottom surface of the interconnection structure 52 is in direct contact with the top surface 32c of the spacer structure 32. The portion of the interconnection structure 52 filling the arc-shaped recess 46 forms a contact bump 52a that is in direct contact and electrically connected to the top electrode 28 of the memory cell structure MC.

In summary, the method for forming a magnetic memory device provided by the present invention additionally performs an etching process to form an arc-shaped recess in the upper portion of the top electrode after defining the trench of the upper layer interconnection structure in the upper dielectric layer. The arc-shaped recess of the top electrode may increase the contacting area with the interconnection structure, so that a reduced and stable contact resistance may be obtained. The present invention may achieve a more stable TMR and a higher TMR ratio, thereby enhancing the performance of the magnetic memory device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming a magnetic memory device, comprising:
forming a memory cell structure on a substrate, the memory cell structure comprising:
a bottom electrode;
a magnetic tunneling junction (MTJ) on the bottom electrode; and
a top electrode on the MTJ;
forming a dielectric layer covering the substrate and the memory cell structure;
forming a trench in the dielectric layer to expose an upper portion of the top electrode;
performing an etching process on the top electrode to from an arc-shaped recess in the upper portion of the top electrode, wherein the arc-shaped recess is below a bottom surface of the trench; and
forming a conductive material to fill the trench and the arc-shaped recess.

2. The method for forming a magnetic memory device according to claim 1, wherein the top electrode has a bullet-shaped cross-section.

3. The method for forming a magnetic memory device according to claim 1, wherein the top electrode comprises:
a lower portion on the MTJ and comprising a straight sidewall; and
the upper portion on the lower portion and comprising a conical sidewall.

4. The method for forming a magnetic memory device according to claim 3, wherein a width of the arc-shaped recess is smaller than a width of the lower portion of the top electrode.

5. The method for forming a magnetic memory device according to claim 3, wherein a lowest point of the arc-shaped recess is not lower than a lower end of the conical sidewall of the upper portion of the top electrode.

6. The method for forming a magnetic memory device according to claim 3, wherein a thickness of the lower portion and a thickness of the upper portion have a ratio of 1:1.

7. The method for forming a magnetic memory device according to claim 1, wherein the etching process is a wet etching process.

8. The method for forming a magnetic memory device according to claim 1, wherein the etching process uses amine-based solvents.

9. The method for forming a magnetic memory device according to claim 1, further comprising forming a spacer structure on a sidewall of the memory cell structure before forming the dielectric layer, wherein after forming the trench, a top surface of the spacer structure is exposed from the trench.

10. The method for forming a magnetic memory device according to claim 9, wherein an edge of the arc-shaped recess borders the spacer structure.

11. A magnetic memory device, comprising:
a memory cell structure on a substrate, the memory cell structure comprising:
a bottom electrode;
a magnetic tunneling junction (MTJ) on the bottom electrode;
a top electrode on the MTJ, wherein an upper portion of the top electrode comprises an arc-shaped recess; and
an interconnection structure disposed on the top electrode and filling the arc-shaped recess.

12. The magnetic memory device according to claim 11, wherein the top electrode comprises:
a lower portion on the MTJ and comprising a straight sidewall; and
the upper portion on the lower portion and comprising a conical sidewall.

13. The magnetic memory device according to claim 12, wherein a width of the arc-shaped recess is smaller than a width of the lower portion of the top electrode.

14. The magnetic memory device according to claim 12, wherein a lowest point of the arc-shaped recess is not lower than a lower end of the conical sidewall of the upper portion of the top electrode.

15. The magnetic memory device according to claim 12, wherein a thickness of the lower portion and a thickness of the upper portion have a ratio of 1:1.

16. The magnetic memory device according to claim 11, further comprising a spacer structure on a sidewall of the memory cell structure, wherein a top surface of the spacer structure is in direct contact with a bottom surface of the interconnection structure.

17. The magnetic memory device according to claim 16, wherein an edge of the arc-shaped recess borders the spacer structure.
